(19) United States
(12) Patent Application Publication
(10) Pub. No.: US 2013/0161773 A1
(43) Pub. Date: Jun. 27, 2013

(54) DETECTOR ELEMENT, RADIATION DETECTOR, MEDICAL DEVICE, AND METHOD FOR PRODUCING SUCH A DETECTOR ELEMENT

(71) Applicants: Fabrice DIERRE, Mohrendorf (DE); Peter HACKENSCHMIED, Nurnberg (DE); Hiroshi KATAKABE, Okinawa (JP); Noriyuki KISHI, Okinawa (JP); Christian SCHRÖTER, Bamberg (DE); Hiroyuki SHIRAKI, Okinawa (JP); Matthias STRASSBURG, Erlangen (DE); Mitsuru TAMASHIRO, Okinawa (JP)

(72) Inventors: Fabrice DIERRE, Mohrendorf (DE); Peter HACKENSCHMIED, Nurnberg (DE); Hiroshi KATAKABE, Okinawa (JP); Noriyuki KISHI, Okinawa (JP); Christian SCHRÖTER, Bamberg (DE); Hiroyuki SHIRAKI, Okinawa (JP); Matthias STRASSBURG, Erlangen (DE); Mitsuru TAMASHIRO, Okinawa (JP)

(21) Appl. No.: 13/721,130

(22) Filed: Dec. 20, 2012

(30) Foreign Application Priority Data
Dec. 23, 2011 (DE) 102011089776.3

(51) Int. Cl. H01L 31/18; H01L 27/146

(52) U.S. Cl. CPC H01L 31/1876; H01L 27/14601
USPC 257/428; 438/73

(57) ABSTRACT

A detector element is disclosed, including a semiconducting converter element and a number of pixilated contacts arranged thereon. A radiation detector is also disclosed including such a detector element, along with a medical device having one or more such radiation detectors. Finally, a method for producing a detector element is disclosed, which includes forming pixelated contacts by way of a photolithographic process on the semiconducting converter element using a lithographic mask arranged on a converter element protective layer.

### PRIORITY STATEMENT

The present application hereby claims priority under 35 U.S.C. §119 to German patent application number DE 10 2011 089 776.3 filed Dec. 23, 2011, the entire contents of which are hereby incorporated herein by reference.

### FIELD

At least one embodiment of the invention generally relates to a detector element having a semiconducting converter element and a number of pixelated contacts arranged thereon, a radiation detector having such a detector element, a medical device having such a radiation detector, and/or a method for producing a detector element having a semiconducting converter element and a number of pixelated contacts arranged thereon.

### BACKGROUND

Directly converting radiation detectors based on semiconductor materials are generally used for detecting ionizing radiation, in particular high-energy x-ray and gamma radiation. In directly converting radiation detectors, individual photons incident on the semiconductor material are counted, consequently enabling the radiation to be verified directly.

For this purpose directly converting radiation detectors typically have detector elements which in addition to the radiation detection material used for detecting ionizing radiation have at least two contacts for at least one anode and one cathode made of a suitable contact material. In this arrangement the radiation detection material and the contact material each have a specific excitation energy of the charge carriers and in the ideal case an ideal ohmic contact exists between the two materials at the interface. This is because the radiation detection material is connected in an electrically conductive manner by way of the anode and/or cathode having the contacts to the readout electronics and the voltage supply of the detector.

Direct-conversion radiation detectors are based for example on radiation detection materials composed of semiconductor compounds having a high atomic number, such as cadmium telluride or cadmium selenide semiconductor systems, for example. By reason of a high x-ray absorption coefficient these materials are suitable in particular for the energy ranges that are typical in medical imaging.

However, a disadvantage of the radiation detectors is the poor hole transport in the semiconductor material and, associated therewith, the trapping of charge carriers in defects which are always present in a real crystal, in particular at grain boundaries and interfaces such as e.g. electrodes. In order to compensate for this disadvantage it is proposed in the prior art to form strips, pixels and other structures of the respective collector electrode, conventionally the anode. All of the surface structures exploit what is referred to as the “small pixel effect”. This is based on the knowledge that in the case of pixelated electrodes which are very small compared to the transducer layer thickness (thickness of the semiconductor layer of the converter element) the weighting field becomes very small in a wide range of the detector and only increases strongly in immediate proximity to the pixelated electrodes. This leads to the greatest part of the charge signal being generated only when the charge carriers reach the vicinity of the electrode. This effect can be used for example in order to reduce the contribution of the signal induced by holes. In this case the efficiency of the “small pixel effect” correlates directly with the ratio between the pixel size and the transducer layer thickness.

In order to produce a transducer layer provided with a surface structure, e.g. a number of pixel elements, the conventional approach is to employ a photolithographic method comprising a plurality of steps, including etching steps, exposure steps, development steps and cleaning steps. Usually, however, this photolithographic method is associated with contaminants and formations of defects which cause the manufacturing costs for such transducer layers or detector elements to rise and often reduce their performance (see e.g. Milof et al. in “Photoresist Process Optimization for Defects Using a Rigorous Lithography Simulator”, IEEE 1997, pp. 57-60).

The cleaning agents used in the manufacture of detector elements for cleaning the surface of the semiconductor converter, in particular to remove undesirable compounds from the surface of the converter element prior to deposition of contacts, also lead to defects. Generally, an etching agent, e.g. a mixture made up of bromine and methanol, is used for cleaning semiconductor elements. However, the freshly etched surfaces of the semiconductor elements are highly reactive. In in-house experiments the inventors have discovered that a lithographic aftertreatment of freshly fabricated or cleaned converter elements often leads to products having undesirable characteristics. Thus, for instance, the application of a photoresist and the subsequently necessary lithography and curing step result in a not inconsiderable degree of surface aging, e.g. due to oxide formation, or in foreign ions being incorporated into the converter element surface.

All these influences alter the properties of the contact material/radiation detection material transition, potentially resulting in interference to the electrical field in the detector element. Thus, for example, polarization effects may be produced, polarization being a phenomenon which causes changes in the electrical field at the converter element surface and consequently also causing changes simultaneously in the counting rate of the detector during operation, the charge storage at the interface, the homogeneity of the detector signal, or a plurality of the properties.

The aforementioned disadvantages were circumvented in the prior art through the use of planar detectors, i.e. converter elements without a pixelated electrode structure. The planar detectors having one or two continuous metal contacts can be manufactured by means of a direct deposition process whereby the contact material is applied to the freshly cleaned, preferably etched contact material surface, with the result that no aging can occur.

### SUMMARY

At least one embodiment of the present invention provides improved detector elements having semiconducting, preferably directly converting, converter elements and pixelated contacts arranged thereon for detecting ionizing radiation, radiation detectors and medical devices having such detector elements, and also a method for producing such detector elements.

Embodiments are directed to a detector element, a radiation detector, a medical device and a method.

The detector element according to an embodiment of the invention comprises a semiconducting converter element and a number of pixelated contacts arranged thereon. According to an embodiment of the invention the contacts, in particular their pixelated structure, can be produced by means of a photolithographic process using a lithographic mask on at least one converter element protective layer. In this case the semiconducting converter element consists of a radiation detection material in which the individual photons which are incident in the material can be counted directly or indirectly. With a directly converting material, the incident radiation can be demonstrated directly by way of a counting rate measurement through the generation of charge carriers in the radiation detection material. With an indirectly converting radiation material used in so-called scintillation detectors, electrons are usually excited in the radiation detection material and converted into photons.

### BRIEF DESCRIPTION OF THE DRAWINGS

The invention is explained in more detail below with the aid of example embodiments and with reference to the attached drawings. The drawings are therefore intended simply to illustrate the invention, but the invention is not to be limited thereto. In the drawings:

FIG. 1 shows a schematic representation of the sequence of individual manufacturing steps for an inventive detector element according to a first embodiment variant,

FIG. 2 show a schematic representation of the sequence of individual manufacturing steps for an inventive detector element according to a second embodiment variant,

FIG. 3 show a schematic representation of the sequence of individual manufacturing steps for an inventive detector element according to a third embodiment variant,

FIG. 4 show a schematic representation of the sequence of individual manufacturing steps for an inventive detector element according to a fourth embodiment variant,

FIG. 5 shows an illustration of a detector element prior to the etching step,

FIG. 6 shows an illustration of a detector element after the etching step,

FIG. 7 shows an example embodiment of a radiation detector according to the invention, and

FIG. 8 shows an example embodiment of a medical device according to the invention.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Before discussing example embodiments in more detail, it is noted that some example embodiments are described as processes or methods depicted as flowcharts. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Methods discussed below, some of which are illustrated by the flow charts, may be implemented by hardware, software, firmware, middleware, microcode, hardware description languages, or any combination thereof. When implemented in software, firmware, middleware or microcode, the program code or code segments to perform the necessary tasks will be stored in a machine or computer readable medium such as a storage medium or non-transitory computer readable medium. A processor(s) will perform the necessary tasks.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

In the following description, illustrative embodiments may be described with reference to acts and symbolic representations of operations (e.g., in the form of flowcharts) that may be implemented as program modules or functional processes include routines, programs, objects, components, data structures, etc., that perform particular tasks or implement particular abstract data types and may be implemented using existing hardware at existing network elements. Such existing hardware may include one or more Central Processing Units (CPUs), digital signal processors (DSPs), application-specific-integrated-circuits, field programmable gate arrays (FPGAs) computers or the like.

Note also that the software implemented aspects of the example embodiments may be typically encoded on some form of program storage medium or implemented over some type of transmission medium. The program storage medium (e.g., non-transitory storage medium) may be magnetic (e.g., a floppy disk or a hard drive) or optical (e.g., a compact disk read only memory, or “CD ROM”), and may be read only or random access. Similarly, the transmission medium may be twisted wire pairs, coaxial cable, optical fiber, or some other suitable transmission medium known to the art. The example embodiments not limited by these aspects of any given implementation.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

The detector element according to an embodiment of the invention comprises a semiconducting converter element and a number of pixelated contacts arranged thereon. According to an embodiment of the invention the contacts, in particular their pixelated structure, can be produced by means of a photolithographic process using a lithographic mask on at least one converter element protective layer. In this case the semiconducting converter element consists of a radiation detection material in which the individual photons which are incident in the material can be counted directly or indirectly. With a directly converting material, the incident radiation can be demonstrated directly by way of a counting rate measurement through the generation of charge carriers in the radiation detection material. With an indirectly converting radiation material used in so-called scintillation detectors, electrons are usually excited in the radiation detection material and converted into photons.

The detector element according to an embodiment of the invention additionally comprises contacts arranged on the converter element for at least one anode and one cathode. At least one of the contacts is a so-called pixelated contact comprising individual pixel elements. It is also implicit in the above definition of the detector element that a pixelated contact is embodied only on the anode side or only on the cathode side of the converter element, whereas it is preferred that such a contact be embodied both on the anode side and on the cathode side.

The requirements in terms of the dimensions of the pixel elements are becoming ever more exacting, with the prior art methods for producing the smallest possible pixel elements already reaching their limits at around 500 μm. Variations in the pixel dimensions of the individual elements in a detector element occur repeatedly, in particular due to the inaccuracies of the conventional manufacturing processes. Inhomogeneities in the counting rate measurement are the result. However, if the contacts in the detector element according to the invention are inventively produced by way of a photolithographic process, the precision of the pixel structure which is necessary in radiation detectors can be achieved.

The detector element according to an embodiment of the invention comprises at least one pixelated contact. “Pixelated contact”, within the meaning of an embodiment of the invention, means that the contact layer (optionally also a plurality of contact layers) possesses a structure which subdivides the contact layer into individual defined pixel elements (referred to as “pixels”). The form and shape of the pixel elements can be chosen at will, the side length or diameter of the individual pixel elements preferably being small compared to the layer thickness of the transducer layer (semiconductor layer) of the converter element in order to achieve the “small pixel effect”.

Preferred structures are circular or rectangular and in particular square pixels, but also pixels having a rectangular footprint and rounded corners, having a defined pixel size, i.e. pixel surface area in the plane of the pixel elements. Example diameters or edge lengths of the pixels are less than 10 mm, preferably less than or equal to 5 mm, further preferably between 100 μm and 500 μm, for example 250 μm. Interstices, e.g. in the form of cavities or grooves, are preferably embodied between the individual pixel elements in the contact layer in order to ensure an electrical separation of the individual pixel elements. The cavities and grooves can also be filled with suitable materials having a resistance that is typically more than an order of magnitude higher than that of the bulk material. Such fillings simultaneously serve as surface protection.

Because the size of the individual pixel elements in the contact layer lies in a previously unattainable dimension and in particular because the homogeneity of the individual pixel elements has been improved in the detector elements according to an embodiment of the invention, the detector elements according to an embodiment of the invention are superior in terms of their polarization properties and the homogeneity of the electrical field compared to the conventionally produced detector elements.

These and further advantages of the detector element according to an embodiment of the invention make it suitable for use in radiation detectors and in particular in detectors for counting rate measurement of x-ray and/or gamma irradiation. For this reason an embodiment of the invention is also directed to a radiation detector having a number of detector elements according to an embodiment of the invention. The detector element according to the invention can comprise pixelated contacts on an anode side and/or on a cathode side. Optionally, the radiation detector can also possess evaluation electronics for reading out a detector signal and able to be embodied e.g. directly as a component part of the radiation detector. Alternatively the evaluation electronics can also be embodied as a separate system which can be connected to the radiation detector.

By virtue of the above-explained advantages and in particular on account of the improvement in terms of the polarization effects and on account of the improved homogeneity of the electrical field, the radiation detectors according to an embodiment of the invention are suitable for use in medical devices even under normal application conditions. They are particularly suitable for use in equipment having a counting rate measurement under x-ray and/or gamma irradiation, in particular at a higher radiation intensity. For this reason, an embodiment of the invention is also directed to a medical device having a radiation detector according to an embodiment of the invention. Such an inventive medical device accordingly comprises a radiation detector as explained in detail hereinabove and an x-ray system, gamma ray system, CT system or radionuclide emission tomography system such as e.g. a PET system or SPECT system.

According to an embodiment of the invention the detector element can be produced by means of a method which comprises at least the step of forming pixelated contacts by means of a photolithographic process on the semiconducting converter element using a lithographic mask arranged on a converter element protective layer. In a photolithographic process (photolithography) the image of a photomask is mapped onto a light-sensitive photoresist (also called a “photosensitive resist”) by way of exposure in a first exposure step. The exposed sites of the photoresist are subsequently dissolved in a development step (negative photolithography). Alternatively it is also possible to dissolve the unexposed sites if the photoresist is cured under light (positive photolithography). This results in a lithographic mask which enables the underlying material, in this case the converter element, to be processed further by means of chemical and physical processes. This can be accomplished for example through the introduction of material into the recesses of the lithographic mask or through the etching of trenches or through the removal of material underneath the recesses in the lithographic mask.

The dependent claims and the following description contain particularly advantageous embodiments and developments of the invention, explicit reference being made to the fact that the inventive radiation detector, the inventive medical device and the inventive method can also be developed further in accordance with the dependent claims relating to the detector element and vice versa.

In a preferred embodiment variant the pixelated contacts can comprise one or more contact layers, in particular metal layers. The individual contact layers can consist of a metal and/or a metal alloy and further preferably comprise a noble metal or noble metal alloy. Examples of metals or noble metals that may be used by preference, either individually or in hybrid or alloy form, are palladium, platinum, gold, ruthenium, iridium, rhodium, copper, nickel, titanium, indium, aluminum, tungsten and molybdenum.

Multilayer contacts consisting, not just of one contact layer, but of two, three or more vertically stacked contact layers are preferred. The number of layers can be chosen arbitrarily provided no or only minor conduction losses occur as a result. Multilayer contacts enable for example the electronic transitions to the radiation detection material, polarization effects, the electron discharge to the evaluation electronics, etc. to be matched to the semiconductor material or the electrodes by means of an appropriate setting of the conductances and/or electronic levels. Different layer structures may also be beneficial in the production of the pixel elements in order for example to enable the etching rates used in the photolithographic processes to be adjusted according to the respective materials. Thus, a platinum layer followed by a gold layer can improve the etching process using potassium hydroxide (platinum is etched approx. 100 times faster than gold), because the layer applied last is more resistant to the etching agent used. The same applies to physical removal processes such as reactive ion etching, plasma etching, etc. Particularly preferred metal layer sequences are Pt/Au or Au/Ni/Au.

In a further preferred embodiment variant of the detector element, the converter element protective layer comprises an insulating layer arranged at the surface of the converter element, in particular an oxide or nitride layer, and/or a layer composed of organic and/or polymer compounds. Examples of such layers are SiO2, Si3N4 or waxes. In a defined thickness, structure and composition, such an oxide, nitride or polymer protective layer can have the property of providing the electronic transition between semiconductor material and contact material in a more durable and reproducible way. Particularly under ambient conditions, such a protective layer is normally significantly less susceptible or reactive than the highly reactive surface of the converter element following its cleaning. In particular when the protective layer is produced shortly or ideally immediately after the cleaning of the surface, aging processes and further impurities can be prevented or at least reduced to a negligible level, thereby improving the reproducibility in particular. Preferred timespans for producing the protective layer following cleaning of the surface range from a few minutes to seconds, e.g. from less than about 10 min, further preferably from less than about 5 min.

The layer thickness of a protective layer, in particular in the form of an oxide layer, is preferably less than approx. 1 μm, further preferably between approx. 1 nm and approx. 500 nm, particularly preferably less than approx. 100 nm, e.g. approx. 20 nm, or even smaller still.

Such an oxide layer can be produced either by applying an oxide onto the converter element surface or by implementing a corresponding oxide phase in the surface layer of the converter element present. The term “arranging” encompasses both these variants as well as production methods for superficial oxide layers that are known as variations to the person skilled in the art. A preferred alternative is the use of an oxygen plasma to produce an oxide at the surface of the semiconductor element. However, alternative plating or deposition methods thereto for oxide layers can also be used in order to produce such a protective layer on or at the converter element surface. Foreign ions such as e.g. halogenides, in particular chlorine, iodine, bromine, can preferably be incorporated into the oxide layer in order to improve the electronic properties even further. The foreign ions enable specific electronic levels to be produced in order to reduce the polarization as a result. Ion implantation techniques for introducing such oxides or halogenated oxides into the upper layers of the converter element are a preferred alternative to the additive methods for producing oxide layers on the surface of the converter element.

Ohmic contacts or Schottky contacts can be formed, depending on the layer thickness of the oxide layer. Other advantages are an improved, i.e. reduced, alteration of the electrical field during operation and consequently a more constant counting rate. When used in a radiation detector this leads overall to improved detector characteristics, in particular in terms of homogeneity and signal stability over time, i.e. drifting of the counting rate with time.

In addition to the above-stated advantages, the oxide layer can not only take on the function of a protective layer against impurities during manufacture, but can also assume the function of a passivation layer between the electrodes.

Alternatively to an oxidic protective layer, as has been explained hereinabove, in a further variant the converter element protective layer of the detector element can comprise one or more contact layers of the contacts. More precisely, the contacts can build up the converter element protective layer themselves or in combination with an oxide layer arranged preferably thereunder. Here, too, impurities due to aging processes etc. of the cleaned and highly reactive surface of the converter element can be reduced or excluded, thereby enabling the lithographic further processing, i.e. the production of pixelated contacts using a lithographic mask applied or created on the contact layer. As a result the radiation detectors produced using such detector elements have an improved homogeneity of the overall detector characteristics, in particular an improved alteration of the electric field during operation and consequently a more constant counting rate measurement.

In a preferred embodiment variant the detector element according to the invention comprises a semiconducting converter element having a radiation detection material which is constructed from semiconductor compounds and in particular semiconductor compounds having directly converting properties. Examples of directly converting semiconductor compounds which can be used in the detector elements according to the invention are II-VI or III-V semiconductor compounds, in particular selenides, tellurides, antimonides, nitrides, arsenides and phosphides, such as, for example, material systems based on CdSe, CdZnTe, CdTeSe, CdZnTeSe, CdMnTeSe, GaSb, GaInSb, GaInAsSb, GaInPSb, AlInSb, AlInAsSb, GaN, GaInN, GaAsN, GaInAsN and InP.

Particularly preferred semiconductor materials on account of their high atomic numbers are CdTe or CdZnTe, CdMnTe and/or the corresponding selenides or hybrid forms, CdxZn1-xTeySe1-y (where 0≦x≦1; 0≦y≦1) and CdxMn1-xTeySe1-y (where 0≦x≦1; 0≦y≦1).

Other semiconductor compounds are composed analogously to the CdTe system explained by way of example hereinabove. With this knowledge, the invention can also be applied to other semiconductor compound systems. Moreover, the above-enumerated semiconductor compounds can additionally be doped with dopants. Such dopants are likewise well-known to the person skilled in the art.

A preferred embodiment variant of the radiation detector according to the invention comprises one of the detector elements explained in detail hereinabove having at least one pixelated contact and optionally evaluation electronics for reading out a detector signal.

Radiation detectors according to an embodiment of the invention can be implemented as Schottky detectors or as ohmic detectors, depending on the detector element used. In a Schottky detector a transition from the semiconductor to the metal (electrode) takes place in one direction only, i.e. such a detector blocks in one direction. In an ohmic detector the electrons can flow in both directions, i.e. from the semiconductor into the metal and vice versa. An ohmic detector therefore does not have the same blocking effect as a Schottky detector.

Such a radiation detector can be embodied as a singular element or as a combined element consisting of two or more individual detectors. A plurality of detectors is usually also referred to as a detector array, which is frequently constructed from an individual semiconductor basic element which has been provided with septa as insulating blocking elements and electrodes. In such a detector array the irradiation is preferably incident on the side of the cathode which has been applied or vapor-deposited onto the semiconductor base element. In a singular detector element the direction of incidence is basically independent of the embodiment of the electrodes and can also come from the side or likewise from the cathode or the anode side

Owing to their improved performance in terms of the contact between the converter element and the contacts and the thus realized prevention of space charge effects and polarization as well as of the more homogeneous electrical field, the detectors according to an embodiment of the invention are suitable for use in a medical device with application of x-ray and/or gamma radiation at high flux densities. Such an inventive medical device accordingly comprises a radiation detector as explained in detail hereinabove and an x-ray system, a gamma ray system, a PET system, a CT system or a SPECT system.

In such devices it is possible to measure high ray fluxes, such as occur in particular in computed tomography, on account of the avoidance or reduction of the polarization at the interfaces between converter element and contact(s) and on account of the more homogeneous electrical field and the more stable signal (improved drift of the counting rate over time). Accordingly, even at ambient temperature a good energy resolution at high ray fluxes can be achieved without great investment in technical apparatus. A further advantage of the use of detector elements having pixelated contacts according to an embodiment of the invention is that very small pixelated contact elements can be produced with a high degree of precision.

A preferred embodiment variant of the method according to the invention comprises the step of cleaning a surface of the semiconducting converter element with a cleaning agent and/or etching agent. The cleaning step is preferably performed prior to the further processing of the converter element, i.e. before a protective layer is applied.

Alternatively, however, the cleaning step can also be performed after a lithographic step for producing the lithographic mask.

If necessary, a beneficial passivation or modification of the surface can be performed after the etching stage. If, for example, the etching process leads to a very hydrophobic surface, it can be beneficial to treat the same appropriately for the metallization step by means of a hydrophilic agent. The advantage of this is that a less hydrophobic surface allows conventional lithography processes and a direct etching prior to the deposition of the contacts.

Examples of cleaning agents or etching agents are mixtures of halogens (e.g. iodine, bromine, etc.) and/or halogen compounds (e.g. bromonaphthalene) and solvents, preferably organic solvents such as e.g. alcohols (e.g. methanol, isopropanol, ethylene glycol). Particularly preferred mixtures are iodine and/or bromine in isopropyl alcohol and/or ethylene glycol, bromonaphthalene in isopropyl alcohol. The halogen concentration in these solutions is preferably in a range from approx. 0.01% to approx. 20%, further preferably from approx. 0.05% to approx. 15%, particularly preferably from approx. 0.1% to approx. 10%. Unless stated otherwise, the specified concentrations always relate to percentages by volume.

Alternative cleaning agents are for example acids, preferably weak acids (e.g. formic acid, acetic acid, phosphoric acid), strong acids (e.g. hydrochloric acid, sulfuric acid, nitric acid) or mixtures thereof. The concentration of the acid in the cleaning agents preferably ranges from approx. 0.1% up to 100%.

The above-enumerated cleaning agents, i.e. the acidic and the halogenated cleaning agents, can be used individually or in any combination with one another, provided they are suitable for cleaning the semiconductor surface of the usual impurities such as deposits, for example, and/or foreign ions such as oxides, for example. The alternative cleaning agents are for example also preferably suitable for removing residues of a photoresist or developer left over from a lithographic process from the semiconductor surface.

A further advantage of such a cleaning step is that fewer residues on the surface also lead to a lower inhomogeneity in the contact-semiconductor interface. The radiation detector produced therefrom delivers a more homogeneous detector performance as a result. Furthermore, a more homogeneous interface also leads to a reduction in the alteration of the electrical field during the operation of the radiation detector and consequently to a more constant counting rate measurement

All in all, such a cleaning step can improve the overall performance of a radiation detector and/or of a medical device. In particular the homogeneity and the temporally constant signal response should be singled out as further advantages attributable to the better homogeneity of the contact-semiconductor interface.

In another preferred embodiment variant of the method according to the invention, an oxide layer can be arranged at the cleaned surface of the semiconducting converter element as a converter element protective layer. By “arranging”, in this context, is to be understood that an additional protective layer having a defined thickness, structure and composition is applied on the surface. The oxide layer serves primarily for embodying an intermediate layer between the lowest contact layer of the contact and the converter surface. Examples of oxidation methods are an oxygen plasma method for producing an oxide or a plating process for creating a beneficial oxide layer on the converter element surface. The deposited oxide layers can include other foreign ions such as halogens (e.g. chlorine) in a mixture, for example.

Alternatively the step of producing the oxide layer can also be accomplished through the introduction of oxide ions into the surface layers of the converter element, for example by means of an ion implantation method. A combination of both methods, i.e. introducing or applying oxide ions into or onto the converter element surface, is beneficial provided a protective layer having defined properties is produced as a result.

Preferably the layers have a thickness of less than 500 nm, further preferably of less than 20 nm, such that any deposition method or ion implementation method can be employed which is capable of producing defined oxide layers in and/or on the surface, in particular with reproducible results.

The photolithographic process applied in the method according to an embodiment of the invention for the purpose of producing a lithographic mask preferably comprises the following steps:

applying a photoresist layer directly or indirectly above a converter element protective layer,

exposing the photoresist layer, and

developing the photoresist layer while forming a lithographic mask.

The photoresist layer is preferably applied directly above the converter element protective layer, for example the oxide layer or contact layer, by way of a standard method, e.g. a doctor-blading or spincoating method. Conventional compounds can be used as a photoresist provided they can be exposed and developed under the given conditions. If necessary, a first curing step, e.g. by heating, can follow in order to prepare the photoresist layer for the development phase.

The photoresist layer is subsequently exposed by means of a photomask and/or by means of a selective exposure of individual regions of the photoresist in order to define the pixel element regions in accordance with a positive or negative photolithographic method. In this case the regions remaining in the development step are cured either by means of photochemical crosslinking and/or by thermal crosslinking.

In the next step, after the definition of the pixel element regions and the corresponding curing, the photoresist layer is developed while the lithographic mask is being formed. The development step is performed by dissolving the uncured photoresist regions (for example using alkali-based agents, preferably a potassium hydroxide solution containing hydrofluoric acid, etc.). A further cleaning step can be performed, for example using the above-enumerated cleaning agents.

The thus produced lithographic mask can either be applied on the contact element layer such that the contact element layer can be etched or removed mechanically through the recesses in the lithographic mask. In this case the contact elements can be produced underneath the photoresist layer, i.e. in the regions in which no etching takes place. In a preferred embodiment variant the method according to the invention therefore comprises the following steps:

producing one or more contact layers as a converter element protective layer or in addition to the converter element protective layer,

applying a lithographic mask, and

structuring the one or more contact layers through the mask.

Alternatively the lithographic mask can also be applied on the oxide layer so that the individual contact elements can be built up by introducing the contact material into the recesses in the lithographic mask, for example a plating of one or more metal layers. Accordingly, a further preferred embodiment variant of the inventive method is characterized by the following steps:

producing a lithographic mask having recesses for the pixelated contacts, and

producing one or more contact layers in the recesses of the lithographic mask.

In another preferred embodiment variant the method according to the invention additionally comprises the step of stripping the lithographic mask while revealing the pixelated contacts. By “stripping” is to be understood both the mechanical removal of the lithographic mask, for example by inducing the photoresist material to swell up and by drawing off the swollen material, or by chemical removal, for example by dissolving the photoresist material. This step can be followed by a rinsing step in order to clean the pixelated contact element structure. The agents employed in the stripping step and rinsing step are matched in terms of the properties of both the photoresist material and the converter element material or contact element material so as to achieve as high a degree of efficiency as possible and cause a minimum degree of damage to the product.

In the method according to an embodiment of the invention, pixelated contacts are particularly preferably produced directly or indirectly on a converter element surface by means of a photolithographic method, the contacts being built up from one or more contact layers. These preferably comprise a metal and/or a metal alloy. If several layers made of different materials are used as the contact element, the uppermost layer, for example, can be embodied in such a way that a developing agent required for the lithography does not attack or dissolve the layer or the layer is resistant thereto. An example of this is a contact consisting of a platinum layer and a gold layer arranged thereon. Since the solubility of gold vis-à-vis hydroxides is 300 times less than that of platinum, a developing agent containing potassium hydroxide can be employed for the photoresist applied on the gold layer. In addition the gold layer acts as an excellent conductor to the electrodes.

The use of one or more metal layers as the contact element is equally advantageous in the manufacture of the detector elements according to an embodiment of the invention in order to utilize suitable agents or removal methods for forming the individual pixel elements. Examples of such structure forming methods are dry etching or liquid etching using suitable chemicals or solutions, reactive ion etching (RIE) or plasma etching, e.g. using an inductively coupled plasma (ICP), ion beam etching, and analogous methods. Dry etching has the advantage inter alia that the etching can be performed in a single step. If it is necessary to etch a plurality of different contact layers, dry etching can be particularly advantageous compared to etching using liquids or solutions, since possibly a number of different etching agents would have to be used for the different materials. Appropriate etching agents both for dry etching and for liquid etching can be matched to the respective materials in the contact layers.

If one or more layers, in particular metal layers, are to be introduced between or into the recesses of a photolithographic mask, well-known deposition methods are suitable for this purpose, such as e.g. vapor phase deposition, plating or sputtering, and similar methods such as e.g. electrochemical or electroless deposition of metals from solutions.

Further advantages of the method according to an embodiment of the invention are that standard processes such as lithography, dry etching, metal deposition methods, etc. can be used in the individual method steps. In this case the high degree of precision of the lithographic method leads to an improved structure and allows a smaller dimensioning of the pixelated contact elements. A detector element or a radiation detector produced in accordance with the inventive method is therefore suitable for use in medical devices for the purpose of measuring high radiation intensities (e.g. greater than 1×109 photons/mm2·s) and consequently for use, for example, in computed tomography examinations.

When detector elements have been manufactured by way of the method according to the invention, they are different from conventionally produced detector elements in terms of their morphology of, for example, the etched contact layers, the thickness and the structure of the oxide layer or of the semiconductor contact element interface. Examination methods for analyzing the oxide layer would be, for example, electron microscope examinations (e.g. by means of SEM). Preferred methods for examining the interface between converter element and metal contact are e.g. secondary ion mass spectrometry (SIMS) or current-voltage measurements (IV measurements).

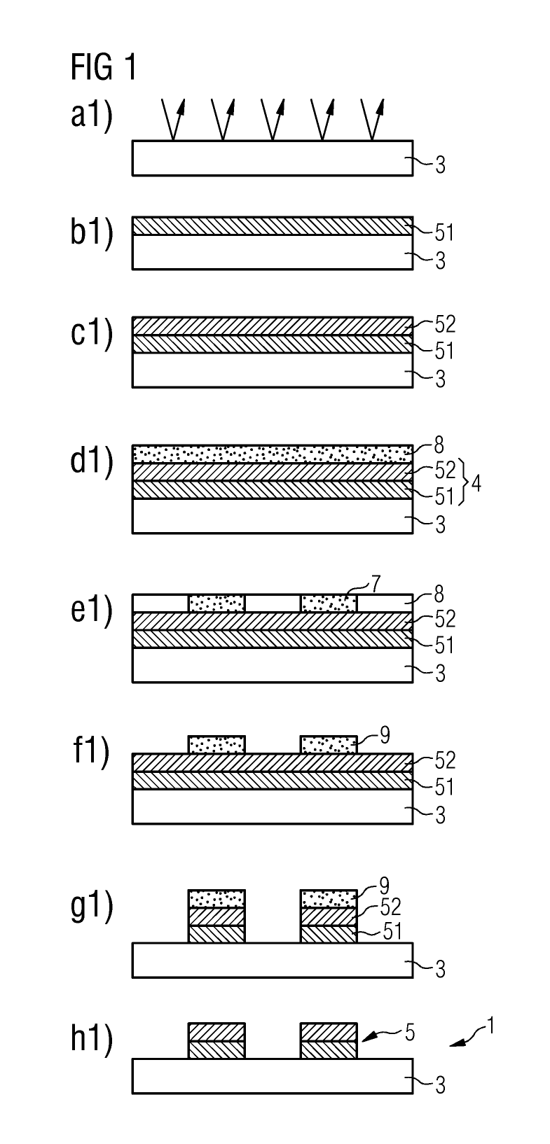

FIG. 1 shows the sequence of individual manufacturing steps for an inventive detector element according to a first embodiment variant.

Firstly, in step a1), a semiconductor converter element 3 is presented and subjected to a cleaning treatment using a cleaning agent, in this case a mixture composed of bromine and methanol (10% bromine fraction), on at least one side of the converter element (in this case the top side). This removes impurities arising from the semiconductor manufacturing process or caused by an aging of the surface, in particular oxides formed thereon, from the surface by etching. A highly reactive semiconductor surface is produced as a result.

In step b1), the freshly cleaned semiconductor surface of the converter element is covered as quickly as possible with a protective layer, in this case a first metal layer 51. In this embodiment variant an approximately 20 nm thick metal layer protecting the highly reactive semiconductor surface is produced as a first contact layer 51 by electroless deposition of platinum (Pt).

An additional metal layer is applied as the second contact layer 52. Optionally, further layers or resist coatings (not shown) can complete the contact layer and serve to protect the underlying converter element surface (step c1)—forming the protective layer 4).

In step d1), a photoresist layer 8 is applied onto the protective layer 4 over its entire surface by means of a spincoating method. The overall layer structure is heated in an oven in order to dry and cure it.

Next, the photoresist layer 8 is exposed through a photomask (not shown) using light, for example laser light at a specific wavelength, at the regions 7 not covered by the photomask, as a result of which the regions 7 of the photoresist layer 8 are crosslinked. The crosslinking leads to a change in the solubility of the photoresist material.

The non-crosslinked regions of the photoresist layer 8 are dissolved out in step f1), the development step of the lithography process, by means of a developing agent, in this case KOH and HF. As a result a lithographic mask 9 remains on the metal layer 52.

In step g1), the pixelated contact elements are structured out of the underlying contact layers through the lithographic mask. Structuring processes or removal processes, such as dry etching or solvent etching for example, are suitable for this purpose. Corresponding etching agents can be used, depending on the material chosen for the metal layers 51 and 52. The etching agent is chosen such that it removes or dissolves the metal layers 51 and 52 relatively selectively, yet attacks the lithographic mask 9 as little as possible. The development step is performed such that the metal layers 51 and 52 are substantially completely removed or dissolved in the regions in which the lithographic mask 9 is not provided. In other words, the surface of the converter element 3 is revealed at these sites and in the process the individual pixel elements 5 are correspondingly separated electrically from one another.

In the next step h1), the lithographic mask 9 is mechanically or chemically stripped or lifted off from the uppermost metal layers 52 in order thereby to reveal the pixelated contacts 5 on the converter element. The thus produced detector element 1 according to the invention can then additionally be cleaned or processed further.

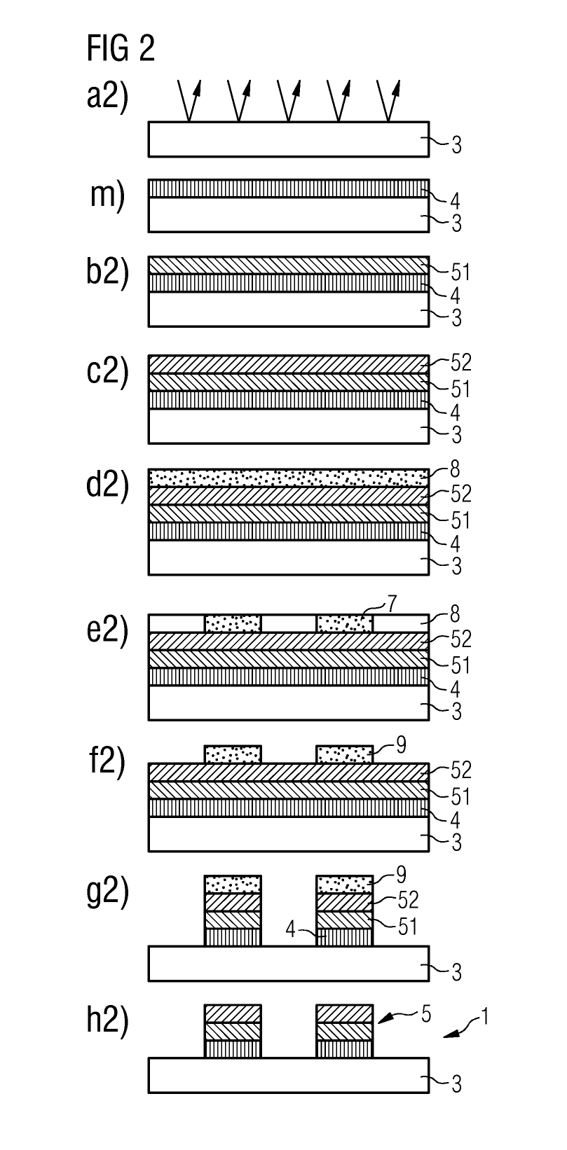

FIG. 2 shows a schematic representation of the sequence of individual manufacturing steps for an inventive detector element according to a second embodiment variant. The method in steps a2) and b2) to h2) is essentially identical to steps a1) to h1) from FIG. 1. The difference compared to the method from FIG. 1 consists in an oxide layer being formed as a protective layer 4 on the converter element 3 in step m) after cleaning step a2). The oxide layer 4 is arranged in a defined thickness on the surface of the converter element 3 by means of an oxygen plasma in order thus to protect its highly reactive surface.

Following the oxide layer 4, a first contact layer 51 and a second contact layer 52 are applied in steps b2) and c2).

A lithographic mask 9 is then formed (steps d2) to f2)) by means of a lithographic process before the pixelated contact elements 5 are structured out (steps g2) and h2)) from the underlying layer structure (stack) by means of reactive ion etching. Both the metal layers 51 and 52 and the oxide layers 4 can be etched, depending on the etching agent used. If desired, the oxide layer 4 can also remain partially or completely on the converter element surface 3 as a protective layer. This embodiment variant is not shown here, but may also be advantageous for subsequent further processing steps in order to protect the converter element surface.

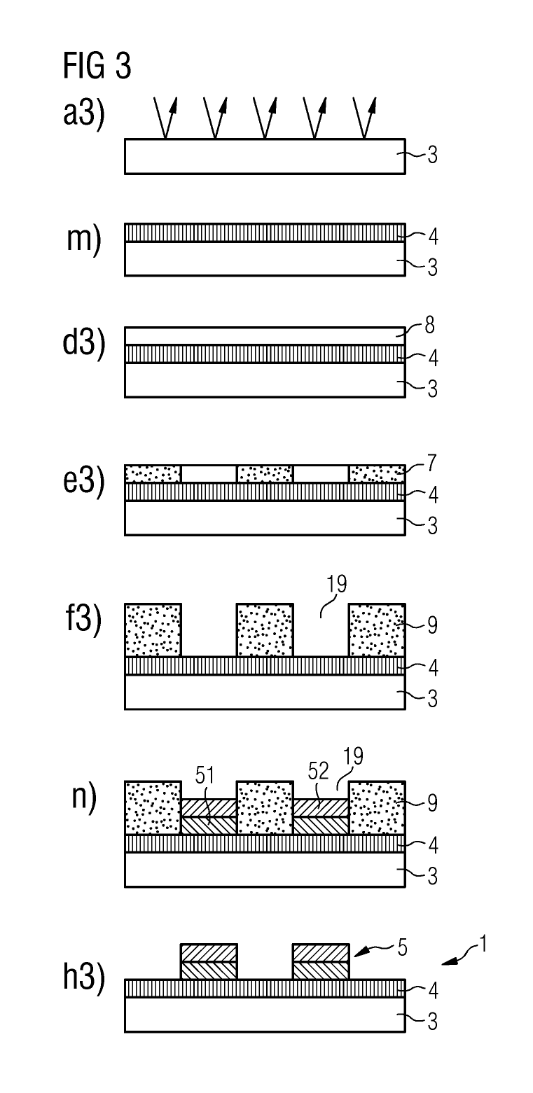

FIG. 3 shows a schematic representation of the sequence of individual manufacturing steps for an inventive detector element according to a third embodiment variant.

In step a3), the converter element 3 is cleaned; this is followed by the production of an oxide layer 4 (step m)) in analogy with the method described in FIG. 2.

A lithographic mask 9 is formed on the oxide layer 4 in steps d3) to f3), as has been described in FIGS. 1 and 2.

In step n), a contact element consisting of a first metal layer 51 and a second metal layer 52 is deposited on the oxide layer 4 into the recesses 19 of the lithographic mask 9 by means of an electroless deposition process.

In step h3), the lithographic mask 9 is mechanically or chemically stripped. This can be effected e.g. through inducing swelling by means of a solvent, as a result of which the lithographic mask 9 can be stripped more easily from the oxide layer 4, for example by applying a lift-off technique to the mask 9 projecting above the metal layers. As a result the finished detector element 1 is produced, comprising a converter element layer 3, an oxide layer 4 and pixelated contacts 5 arranged thereabove. Further processing steps can follow in this case also, in particular cleaning steps or refinement steps.

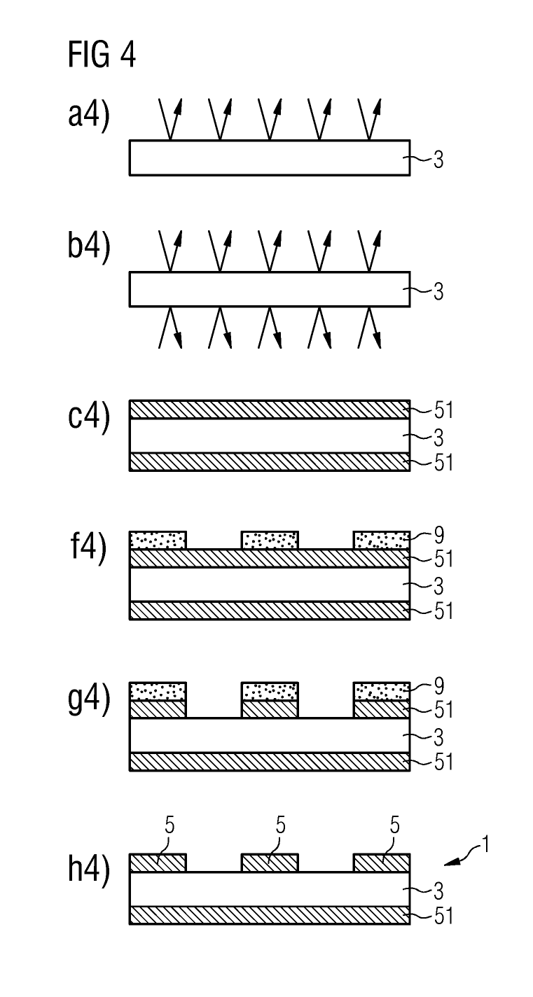

FIG. 4 shows a schematic representation of the sequence of individual manufacturing steps for an inventive detector element according to a fourth embodiment variant.

In step a4), a converter element 3 is presented whose top and bottom sides are cleaned in the subsequent step b4), and specifically using a mixture of bromine and methanol.

In step c4), a metal layer 51 is deposited both from the top side and from the bottom side. Optionally, this can also be followed by further metal layers or contact element layers (not shown).

In step f4), a lithographic mask 9 is produced on the top side by way of a lithography process.

Next, in step g4), the underlying metal layer 51 is etched out or mechanically removed in the uncovered regions through the lithographic mask 9.

The stripping of the photolithographic mask 9 in step h4) leads to the revealing of the contacts 5, which have a pixelated structure. The detector element 1 resulting therefrom has, in this order, a bottom metal layer 51 formed over the entire surface, a converter element 3, and pixelated contacts 5. In this case the contacts can be embodied from one or more contact layers, preferably metal layers. If desired, the bottom metal layer 51 can also be structured as a pixelated layer.

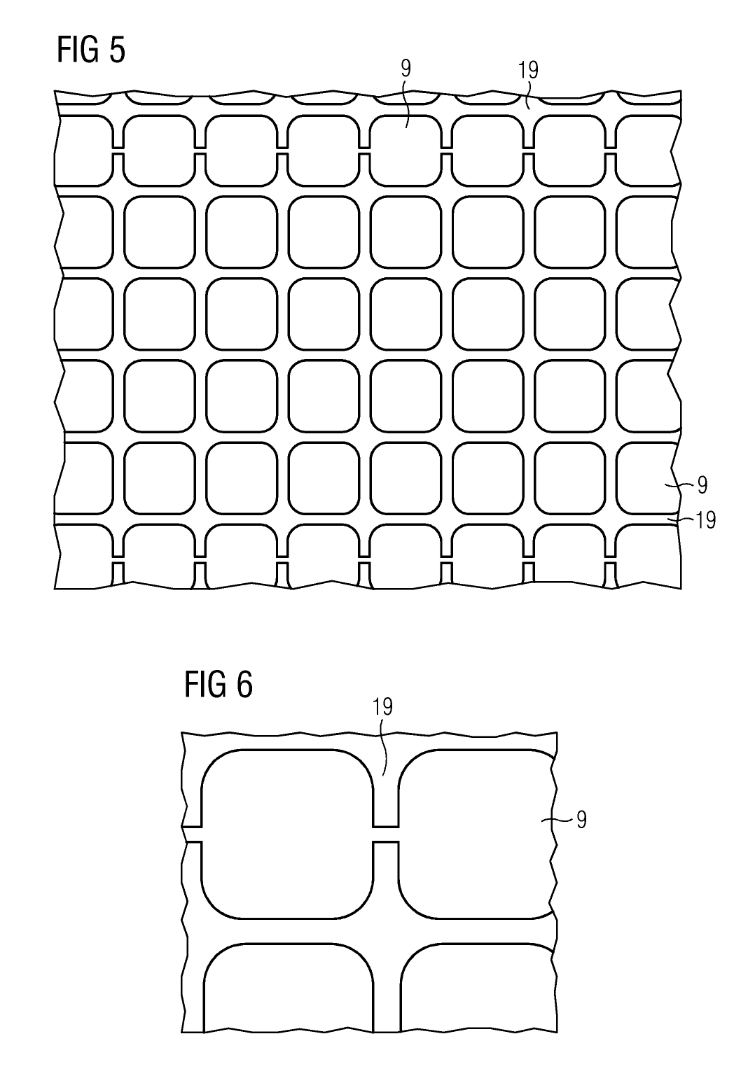

FIG. 5 shows an illustration of a detector element produced in accordance with the manufacturing steps schematically represented in FIG. 4 after the production of a photolithographic mask 9, i.e. after step f4). In the plan view can be seen the cured regions of the mask 9 remaining after the development step, with the excavated recesses 19. This is the state prior to the following etching step.

FIG. 6 shows an illustration of the detector element from FIG. 5 after the etching step g4). The regions covered by the mask 9 remain virtually unchanged during the etching step, i.e. essentially no material removal takes place here. In the regions of the recesses 19 the metal layer which can be seen in the recesses is removed except for the converter element (darker areas).

Following the stripping of the photolithographic mask 9 the contacts lying thereunder (not shown) are revealed. These have substantially the same dimension and shape as the mask regions 9. This means that a well-defined pixel pattern can be produced easily and with a high degree of precision from contact material on a converter element, even when the individual pixel elements have a side length of less than approximately 250 nm. The thus produced detector elements are exceptionally well suited for radiation detectors or medical devices which are capable of measuring high radiation intensities (e.g. >1×109). They can therefore be used to excellent effect in computed tomography applications.

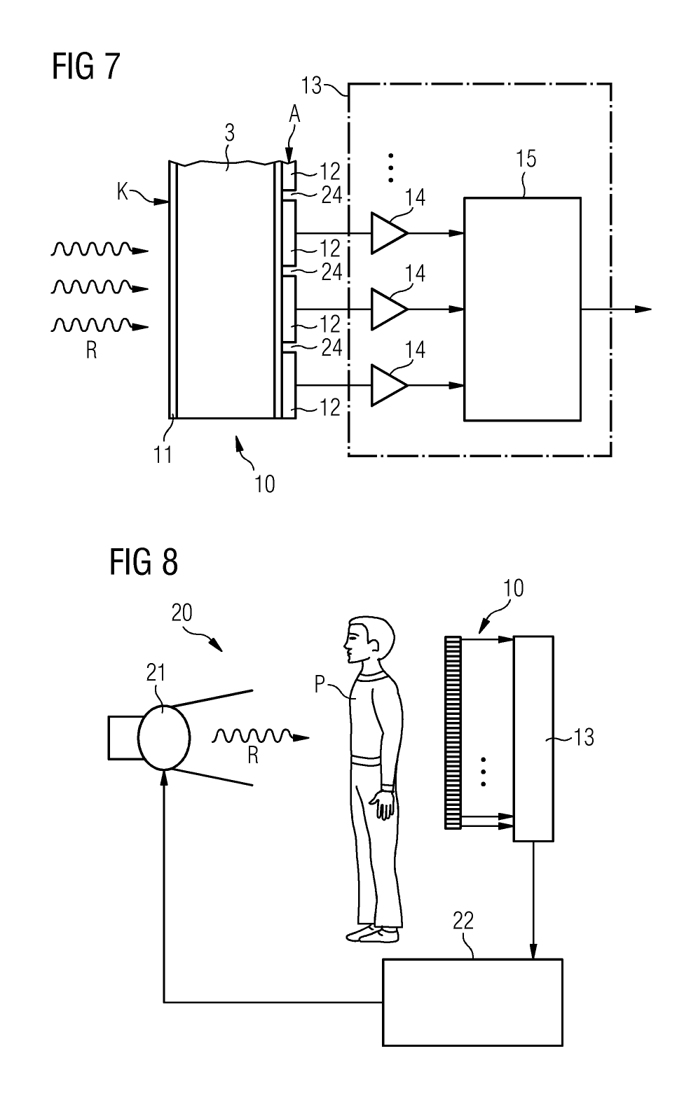

FIG. 7 shows an example embodiment of an inventive radiation detector 10 which in this case is equipped with evaluation electronics 13. According to the invention the detector element in this case comprises a converter element 3 completely covered by a contact layer 11 on the cathode K side. The pixelated contacts 12 on the anode A side are arranged adjacent to one another in a matrix-like array (only a section of one row of the detector element is shown in FIG. 7) and are separated from one another by recesses or septa 24.

The ionizing radiation that is to be detected, e.g. x-ray radiation R, is incident here on the cathode side of the radiation detector 10. In principle, however, a radiation detector according to the invention can also be embodied in such a way that the radiation R that is to be detected strikes the radiation detector from a different direction of incidence, for example that the radiation detector is aligned such that the cathode side and the anode side lie parallel to the direction of incidence of the radiation.

In this case the radiation detector 10 is provided with evaluation electronics 13 having a preamplifier 14 for each pixelated contact element 12 in order initially to preamplify a signal being generated in the converter element 3 and conducted to a pixelated contact element 12. The coupling of the preamplifier 14 to the anodes A is depicted in greatly simplified form in the figure. The basic methods of how signals can be read out from a radiation detector and processed further are well-known to the person skilled in the art. The preamplifiers 14 are connected to a signal processing device 15 in which the signals are processed further and then passed on e.g. to an evaluation unit (not shown).

FIG. 8 shows a very simple example embodiment of a medical device 20, in this case an x-ray system 20. This has an x-ray emitter 21, a radiation detector 10 having evaluation electronics 13 and a system control device 22. During operation the x-ray emitter 21 and the radiation detector 10 are arranged opposite each other such that the radiation direction of the x-ray emitter 21 points in the direction of the radiation detector 10. An examination object P, for example a patient or a part of the patient's body, is then suitably positioned between the x-ray emitter 21 and the radiation detector 10 in order to register in a spatially resolved manner by way of the radiation detector 10 the x-ray radiation R emitted by the x-ray emitter 21 and attenuated by the examination object P for the purpose of recording an x-ray image. The x-ray emitter 21 is controlled in this case by means of a system control device 22, depicted in greatly simplified form, which also takes over the detector signals processed by the evaluation electronics 13 for further processing, in order for example to reconstruct an image from the detector signals and output the image to a user or store it in a memory.

In conclusion it is once again pointed out that the detector elements, radiation detectors, medical devices and methods for producing detector elements described in detail hereinabove are merely preferred example embodiments which can be modified by the person skilled in the art in different ways without leaving the scope of the invention insofar as it is specified by means of the claims. In particular the same or at least similar effects can be achieved if a pixilated contact is employed only on one side, either the anode or the cathode side, of such a detector element. For the sake of completeness it is also pointed out that the use of the indefinite article “a” or “an” does not preclude the possibility that the features in question may also be present more than once. Equally, the term “element” as a component part does not preclude the latter consisting of a plurality of components which in certain circumstances may also be spatially distributed.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, tangible computer readable medium and tangible computer program product. For example, of the aforementioned methods may be embodied in the form of a system or device, including, but not limited to, any of the structure for performing the methodology illustrated in the drawings.

Even further, any of the aforementioned methods may be embodied in the form of a program. The program may be stored on a tangible computer readable medium and is adapted to perform any one of the aforementioned methods when run on a computer device (a device including a processor). Thus, the tangible storage medium or tangible computer readable medium, is adapted to store information and is adapted to interact with a data processing facility or computer device to execute the program of any of the above mentioned embodiments and/or to perform the method of any of the above mentioned embodiments.

The tangible computer readable medium or tangible storage medium may be a built-in medium installed inside a computer device main body or a removable tangible medium arranged so that it can be separated from the computer device main body. Examples of the built-in tangible medium include, but are not limited to, rewriteable non-volatile memories, such as ROMs and flash memories, and hard disks. Examples of the removable tangible medium include, but are not limited to, optical storage media such as CD-ROMs and DVDs; magneto-optical storage media, such as MOs; magnetism storage media, including but not limited to floppy disks (trademark), cassette tapes, and removable hard disks; media with a built-in rewriteable non-volatile memory, including but not limited to memory cards; and media with a built-in ROM, including but not limited to ROM cassettes; etc. Furthermore, various information regarding stored images, for example, property information, may be stored in any other form, or it may be provided in other ways.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A detector element, comprising:
a semiconducting converter element; and
a plurality of pixilated contacts arranged thereon, wherein the contacts are produced by way of a photolithographic process using a lithographic mask on at least one converter element protective layer.

2. The detector element of claim 1, wherein the contacts comprise one or more contact layers composed of at least one of a metal and a metal alloy.

3. The detector element of claim 1, wherein the converter element protective layer comprises an insulating layer arranged at the surface of the converter element.

4. The detector element of claim 1, wherein the converter element protective layer comprises one or more contact layers of the contacts.

5. The detector element of claim 1, wherein the semiconducting converter element comprises a radiation detection material consisting of at least one of CdₓZn₁₋ₓTe_{y}Se_{1-y} (where 0≦x≦1; 0≦y≦1) and CdₓMn₁₋ₓTe_{y}Se_{1-y} (where 0≦x≦1; 0≦y≦1).

6. A radiation detector comprising:
a number of detector elements of claim 1, wherein the detector elements comprise pixelated contacts on at least one of an anode side and a cathode side.

7. A medical device comprising one or more radiation detectors of claim 6.

8. A method for producing a detector element including a semiconducting converter element and a number of pixilated contacts arranged thereon, the method comprising:
forming pixelated contacts by way of a photolithographic process on the semiconducting converter element using a lithographic mask arranged on a converter element protective layer.

9. The method for producing a detector element of claim 8, further comprising:
cleaning a surface of the semiconducting converter element with at least one of a cleaning agent and etching agent.

10. The method for producing a detector element of claim 8, comprising:
arranging an oxide layer on the cleaned surface of the semiconducting converter element as a converter element protective layer.

11. The method for producing a detector element of claim 8, wherein the photolithographic process comprises producing a lithographic mask comprising:
applying a photoresist layer directly or indirectly above a converter element protective layer,
exposing the photoresist layer, and
developing the photoresist layer while forming a lithographic mask.

12. The method for producing a detector element of claim 8, wherein the forming of the pixelated contacts comprises:
producing one or more contact layers as a converter element protective layer or in addition to the converter element protective layer,
applying a lithographic mask, and
structuring the one or more contact layers through the mask.

13. The method for producing a detector element of claim 8, wherein the forming of the pixelated contacts comprises:
producing a lithographic mask having recesses for the pixelated contacts, and
producing one or more contact layers in the recesses of the lithographic mask.

14. The method for producing a detector of claim 8, further comprising stripping the lithographic mask while revealing the pixelated contacts.

15. The method of claim 8, wherein the contacts are produced from one or more contact layers composed of at least one of a metal and a metal alloy.

16. The detector element of claim 3, wherein the converter element protective layer comprises at least one of an oxide or nitride layer, and a layer composed of at least one of organic and polymer compounds.

17. The radiation detector of claim 6, further comprising:
evaluation electronics for reading out a detector signal.

18. The method for producing a detector element of claim 9, comprising:
arranging an oxide layer on the cleaned surface of the semiconducting converter element as a converter element protective layer.
